(19) United States
(12) Patent Application Publication
(10) Pub. No.: US 2023/0317842 A1
(43) Pub. Date: Oct. 5, 2023

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Masakazu BABA, Matsumoto-city (JP); Shinsuke HARADA, Tsukuba-city (JP)

(73) Assignee: FUJI ELECTRIC CO., LTD., Kawasaki-shi (JP)

(21) Appl. No.: 18/176,130

(22) Filed: Feb. 28, 2023

(30) Foreign Application Priority Data
Mar. 22, 2022 (JP) 2022-044877

(51) Int. Cl. H01L 29/16; H01L 29/66; H01L 29/78

(52) U.S. Cl. CPC H01L 29/7811; H01L 29/1608; H01L 29/66068

(57) ABSTRACT

In an active region, a first parallel pn layer is provided in which a plurality of first first-conductivity-type regions and a plurality of first second-conductivity-type regions are disposed so as to repeatedly alternate with one another; in a termination region, a second parallel pn layer is provided in which a plurality of second first-conductivity-type regions and a plurality of second second-conductivity-type regions are disposed so as to repeatedly alternate one another; in the termination region, a first semiconductor region of a second conductivity type, is selectively provided between a first main surface of a semiconductor substrate and the second parallel pn layer, the first semiconductor region configuring a voltage withstanding structure and surrounding a periphery of the active region. An other second-conductivity-type region between the first semiconductor region and the plurality of second second-conductivity-type regions in a thickness direction is provided and has a thickness of 0.1 µm or less.

### CROSS REFERENCE TO RELATED APPLICATIONS

This application is based upon and claims the benefit of priority of the prior Japanese Patent Application No. 2022-044877, filed on Mar. 22, 2022, the entire contents of which are incorporated herein by reference.

### BACKGROUND OF THE INVENTION

### 1. Field of the Invention

Embodiments of the invention relate to a silicon carbide semiconductor device and a method of manufacturing a silicon carbide semiconductor device.

### 2. Description of the Related Art

A semiconductor device that has a superjunction (SJ) structure in which a drift layer is a parallel pn layer in which n-type regions and p-type regions are disposed adjacent to one another so as to repeatedly alternate with one another in a direction parallel to a main surface of a substrate is conventionally known. N-type regions and p-type regions that configure the parallel pn layer extend in a striped pattern in a semiconductor substrate (semiconductor chip), at a main surface thereof. The n-type regions and the p-type regions configuring the parallel pn layer are substantially uniform in substantially an entire area of the semiconductor substrate, from an active region in a center (chip center) of the semiconductor substrate to an end (chip end) of the semiconductor substrate.

A structure of a conventional silicon carbide semiconductor device having a SJ structure is described taking, as an example, a metal oxide semiconductor field effect transistor (MOSFET) having insulated gates with a three-layer structure including a metal, an oxide film, and a semiconductor. FIG. 20 is a plan view of a layout when the conventional silicon carbide semiconductor device is viewed from a front side of the semiconductor substrate thereof. FIGS. 21 and 22 are cross-sectional views of the structure along cutting line AA-AA′ and cutting line BB-BB′ in FIG. 20.

A conventional silicon carbide semiconductor device 150 depicted in FIGS. 20 to 22, in an active region 110 of a semiconductor substrate (semiconductor chip) 140 thereof containing silicon carbide, has a general trench gate structure and is a vertical MOSFET with a SJ structure in which a drift layer 102 is constituted by a parallel pn layer 151. The semiconductor substrate 140 has a rectangular shape in a plan view. The active region 110 has a substantially rectangular shape in a plan view and is provided in a center (the chip center) of the semiconductor substrate 140. A periphery of the active region 110 is surrounded by an edge termination region 130 with an intermediate region 120 intervening therebetween.

A gate wiring layer (not depicted) such as a gate runner is disposed in the intermediate region 120. The edge termination region 130 is a region between the intermediate region 120 and an end (the chip end) of the semiconductor substrate 140. In the edge termination region 130, a junction termination extension (JTE) structure 132 and an n⁺-type channel stopper region 134 are disposed as a voltage withstanding structure. The JTE structure 132 surrounds the periphery of the active region 110 with the intermediate region 120 intervening therebetween.

The n⁺-type channel stopper region 134 is closer to the chip end than is the JTE structure 132, is disposed apart from the JTE structure 132, and reaches the end of the semiconductor substrate 140. The n⁺-type channel stopper region 134 extends along the end of the semiconductor substrate 140 and surrounds a periphery of the JTE structure 132. In FIG. 20, an inner periphery of the n⁺-type channel stopper region 134 is indicated by a dashed line 134a. The n⁺-type channel stopper region 134 is provided in an entire area from the dashed line 134a to the chip end and a periphery of the n⁺-type channel stopper region 134 is the end of the semiconductor substrate 140.

The parallel pn layer 151 is provided substantially uniformly in substantially an entire area of the semiconductor substrate 140, spanning the active region 110 to the edge termination region 130. The parallel pn layer 151 constitutes the SJ structure in which n-type regions 152 and p-type regions 153 are disposed adjacently to one another so as to repeatedly alternate with one another in a first direction X parallel to a front surface of the semiconductor substrate 140. The n-type regions 152 and the p-type regions 153 of the parallel pn layer 151 extend in a striped pattern a second direction Y that is parallel to the front surface of the semiconductor substrate 140 and orthogonal to the first direction X. In FIG. 20, the p-type regions 153 is indicated by hatching.

The n-type regions 152 and the p-type regions 153 of the parallel pn layer 151 are disposed in substantially an entire area of the edge termination region 130, directly beneath (side facing an n⁺-type drain region 101 (refer to FIGS. 21 and 22)) the JTE structure 132 and the n⁺-type channel stopper region 134. In the entire periphery of the JTE structure 132 and the n⁺-type channel stopper region 134, the parallel pn layer 151 is adjacent to the JTE structure 132 and the n⁺-type channel stopper region 134 in a depth direction Z and reaches the front surface of the semiconductor substrate 140 between the JTE structure 132 and the n⁺-type channel stopper region 134.

A cross-section of the structure of the conventional silicon carbide semiconductor device 150 is described. The semiconductor substrate 140 epitaxial layers 142, 143 constituting the drift layer 102 and a p-type base region 104 are sequentially stacked on an n⁺-type starting substrate 141 containing silicon carbide. The semiconductor substrate 140 has, as the front surface, a main surface having the p-type epitaxial layer 143 and, as a back surface, has a main surface having the n⁺-type starting substrate 141, which constitutes the n⁺-type drain region 101. The n⁻-type epitaxial layer 142 is a portion that constitutes the drift layer (drift region) 102 and includes the parallel pn layer 151.

A portion of the p-type epitaxial layer 143 in the edge termination region 130 is removed by etching, thereby forming a drop 131 at the front surface of the semiconductor substrate 140. The front surface of the semiconductor substrate 140 has a portion (hereinafter, first portion) 140a that is closer to the active region 110 than is the drop 131 and a portion (hereinafter, second portion) 140b that is closer to the edge termination region 130 than is the first portion 140a and that is recessed toward the n⁺-type drain region 101. A reference character 140c is a portion (hereinafter, third portion) of the front surface of the semiconductor substrate 140, connecting the first portion 140a and the second portion 140b.

In the edge termination region 130, the n⁻-type epitaxial layer 142 is exposed at the second portion 140b of the front surface of the semiconductor substrate 140. In the semiconductor substrate 140, at the second portion 140b of the front surface thereof, the p-type regions configuring the JTE structure 132 and the n⁺-type channel stopper region 134 are each selectively provided in the n⁻-type epitaxial layer 142. In FIGS. 21 and 22, the p-type regions configuring the JTE structure 132 and disposed adjacently to one another in concentric shapes surround the periphery of the active region 110 are depicted as a single p⁻-type region 133.

The p⁻-type region 133 of the JTE structure 132 is fixed to a potential of a source electrode (not depicted), via a p⁺-type outer peripheral region 113 that extends closer to the chip end from the active region 110 than is the drop 131. A portion of the p⁺-type outer peripheral region 113 closer to the chip end than is the drop 131, the p⁻-type region 133 of the JTE structure 132, and the n⁺-type channel stopper region 134 are exposed at the second portion 140b of the front surface of the semiconductor substrate 140. Being exposed at the second portion 140b of the front surface of the semiconductor substrate 140 means being in contact with a field insulating film 135 on the second portion 140b.

The n-type regions 152 and the p-type regions 153 of the parallel pn layer 151 are disposed at equal intervals in the entire area of the semiconductor substrate 140, spanning the active region 110 to the edge termination region 130. The n-type regions 152 and the p-type regions 153 of the parallel pn layer 151 are disposed directly beneath the p⁺-type outer peripheral region 113 in the intermediate region 120, directly beneath the p⁻-type region 133 and the n⁺-type channel stopper region 134 in the edge termination region 130, and are in contact with the p⁺-type outer peripheral region 113, the p⁻-type region 133, and the n⁺-type channel stopper region 134 in the depth direction Z.

The n-type regions 152 and the p-type regions 153 of the parallel pn layer 151 are exposed at the second portion 140b of the front surface of the semiconductor substrate 140, between the p⁻-type region 133 and the n⁺-type channel stopper region 134 of the JTE structure 132. Carrier concentrations (impurity concentrations) and widths (widths in the first direction X) Wn, Wp of the n-type regions 152 and the p-type regions 153 of the parallel pn layer 151 are set so that charge balance is obtained between the n-type regions 152 and the p-type regions 153 that are adjacent to one another in the parallel pn layer 151.

Charge balance being obtained means that an amount of charge expressed by a product obtained by multiplying the carrier concentration and the width Wn of the n-type regions 152 and an amount of charge expressed by a product obtained by multiplying the carrier concentration and the width Wp of the p-type regions 153 are substantially the same within a range that includes an allowable error due to process variation. Reference character 102a is a normal n-type drift region that is between the parallel pn layer 151 and the n⁺-type drain region 101 and that does not constitute the SJ structure. Reference numerals 114, 116, and 136 are an interlayer insulating film, a drain electrode, and a passivation film.

According to a known method of manufacturing the conventional silicon carbide semiconductor device having the SJ structure, an ion implantation process is performed with respect to predetermined regions of a surface of a drift region, whereby a RESURF layer of a second conductivity type is formed so as to span multiple pillar regions (for example, refer to International Publication No. WO 2017/212773).

### SUMMARY OF THE INVENTION

According to an embodiment of the invention, a silicon carbide semiconductor device includes: a semiconductor substrate containing silicon carbide, the semiconductor substrate having a first main surface and a second main surface that are opposite to each other, the semiconductor substrate further having an active region and a termination region surrounding a periphery of the active region; a first parallel pn layer in which a plurality of first first-conductivity-type regions and a plurality of first second-conductivity-type regions are disposed so as to repeatedly alternate with one another in a direction parallel to the first main surface of the semiconductor substrate, the first parallel pn layer being provided in the semiconductor substrate, in the active region; a second parallel pn layer in which a plurality of second first-conductivity-type regions and a plurality of second second-conductivity-type regions are disposed so as to repeatedly alternate with one another in the direction, the second parallel pn layer being provided in the semiconductor substrate, in the termination region; a device structure provided between the first main surface of the semiconductor substrate and the first parallel pn layer, in the active region; a first electrode provided on the first main surface of the semiconductor substrate, the first electrode being electrically connected to the device structure; a second electrode provided on the second main surface of the semiconductor substrate; and a first semiconductor region of the second conductivity type configuring a voltage withstanding structure and being electrically connected to the first electrode, the first semiconductor region being selectively provided between the first main surface of the semiconductor substrate and the second parallel pn layer in the termination region, the first semiconductor region surrounding the periphery of the active region. The first semiconductor region has an overlap area where the first semiconductor region and one of the plurality of second second-conductivity-type regions overlap each other in a plan view of the silicon carbide semiconductor device. In the overlap area, the first semiconductor region and the one of the plurality of second second-conductivity-type regions are in contact with each other in a thickness direction, or between the first semiconductor region and the one of the plurality of second second-conductivity-type regions in the thickness direction, another second-conductivity-type region is provided and has a thickness of at most 0.1 µm.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view of a layout when a silicon carbide semiconductor device according to a first embodiment is viewed from a front side of a semiconductor substrate thereof.

FIG. 2 is a cross-sectional view of a structure of an active region.

FIG. 3 is a cross-sectional view of the structure along cutting line A1-A2 in FIG. 1.

FIG. 4 is a cross-sectional view of the structure along cutting line A2-A3 in FIG. 1.

FIG. 5 is a detailed cross-sectional view of a JTE structure of the silicon carbide semiconductor device according to the first embodiment.

FIG. 6 is a detailed cross-sectional view of the JTE structure of the silicon carbide semiconductor device according to the first embodiment.

FIG. 7 is a graph depicting results of simulation of breakdown voltage of an edge termination region of the silicon carbide semiconductor device according to the first embodiment.

FIG. 8A is a figure showing results of simulation of depletion layer distribution of the silicon carbide semiconductor device according to the first embodiment.

FIG. 8B is a figure showing results of simulation of depletion layer distribution of the silicon carbide semiconductor device according to the first embodiment.

FIG. 8C is a figure showing results of simulation of depletion layer distribution of the silicon carbide semiconductor device according to the first embodiment.

FIG. 9A is a figure depicting results of simulation of current density distribution of the silicon carbide semiconductor device according to the first embodiment.

FIG. 9B is a figure depicting results of simulation of current density distribution of the silicon carbide semiconductor device according to the first embodiment.

FIG. 9C is a figure depicting results of simulation of current density distribution of the silicon carbide semiconductor device according to the first embodiment.

FIG. 9D is a figure showing current density values in FIGS. 9A to 9C.

FIG. 10A is a figures showing results of simulation of space charge distribution for the silicon carbide semiconductor device according to the first embodiment.

FIG. 10B is a figures showing results of simulation of space charge distribution for the silicon carbide semiconductor device according to the first embodiment.

FIG. 10C is a figures showing results of simulation of space charge distribution for the silicon carbide semiconductor device according to the first embodiment.

FIG. 10D is a figure showing values of the space charge in FIGS. 10A to 10C.

FIG. 11 is a detailed cross-sectional view of the JTE structure of the silicon carbide semiconductor device according to a second embodiment.

FIG. 12 is a detailed cross-sectional view of the JTE structure of the silicon carbide semiconductor device according to the second embodiment.

FIG. 13 is a cross-sectional view of a state of the JTE structure of the silicon carbide semiconductor device according to the second embodiment during manufacture.

FIG. 14 is a detailed cross-sectional view of the JTE structure of the silicon carbide semiconductor device according to a third embodiment.

FIG. 15 is a detailed cross-sectional view of the JTE structure of the silicon carbide semiconductor device according to the third embodiment.

FIG. 16 is a graph depicting impurity concentration of the JTE structure of the silicon carbide semiconductor device according to the third embodiment.

FIG. 17 is a detailed cross-sectional view of the JTE structure of the silicon carbide semiconductor device according to a fourth embodiment.

FIG. 18 is a detailed cross-sectional view of the JTE structure of the silicon carbide semiconductor device according to the fourth embodiment.

FIG. 19 is a plan view of a layout when the silicon carbide semiconductor device according to a fifth embodiment is viewed from the front side of the semiconductor substrate thereof.

FIG. 20 is a plan view of a layout when a conventional silicon carbide semiconductor device is viewed from a front side of a semiconductor substrate thereof.

FIG. 21 is a cross-sectional view of a structure along cutting line AA-AA′ in FIG. 20.

FIG. 22 is a cross-sectional view of the structure along cutting line BB-BB′ in FIG. 20.

FIG. 23 is a detailed cross-sectional view of a JTE structure of the conventional silicon carbide semiconductor device.

FIG. 24 is a detailed cross-sectional view of the JTE structure of the conventional silicon carbide semiconductor device.

FIG. 25 is a cross-sectional view before the JTE structure of the conventional silicon carbide semiconductor device is configured.

### DETAILED DESCRIPTION OF THE INVENTION

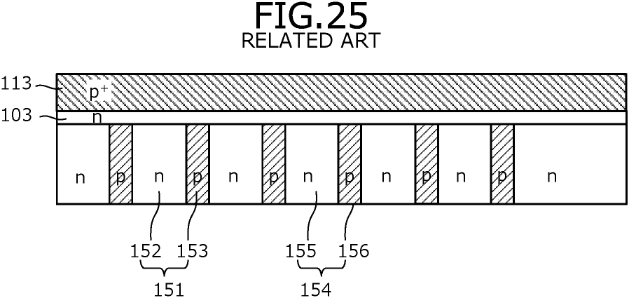

First, problems related to the conventional techniques are discussed. FIGS. 23 and 24 are detailed cross-sectional views of the JTE structure of the conventional silicon carbide semiconductor device. FIG. 23 is a cross-sectional view of the structure along cutting line AA-AA′ in FIG. 20; FIG. 24 is a cross-sectional view of the structure along cutting line BB-BB′ in FIG. 20. As depicted in FIGS. 23 and 24, the JTE structure 132 may be a double-zone JTE structure. The double-zone JTE structure is a structure in which the JTE structure 132 is configured by two p-type regions (a p⁻-type region 132a and a p⁻⁻-type region 132b closer to the chip end than is the p⁻-type region 132a) that are adjacent to each other.

FIG. 25 is a cross-sectional view before the JTE structure of the conventional silicon carbide semiconductor device is configured. In the edge termination region 130, the p⁺-type outer peripheral region 113 and an n-type current spreading region 103 are deposited on surfaces of the n-type regions 152 and the p-type regions 153. When a mesa structure is formed, the entire p⁺-type outer peripheral region 113 is etched and the n-type current spreading region 103 is partially etched. Thereafter, a p-type impurity such as aluminum (Al) is ion-implanted, whereby the JTE structure 132 is formed. Thus, the JTE structure 132 is electrically connected to the p-type regions 153 of the parallel pn layer 151. As a result, when high voltage is applied to the semiconductor device, electric field that concentrates in the edge termination region 130 portion is mitigated, whereby a desired breakdown voltage (BV) is obtained.

Nonetheless, in the conventional silicon carbide semiconductor device, regions (in FIGS. 23 and 24, regions A surrounded by dotted lines) where the p-type regions 153 and the JTE structure 132 overlap are present, and the p-type impurity concentration locally increases. Therefore, a problem arises in that in the JTE structure 132, above the overlapping regions, the spreading of a depletion layer is inhibited, nondepleted areas become paths of leakage current, and the breakdown voltage decreases.

Embodiments of a silicon carbide semiconductor device according to the present invention are described in detail with reference to the accompanying drawings. In the present description and accompanying drawings, layers and regions prefixed with n or p mean that majority carriers are electrons or holes. Additionally, + or - appended to n or p means that the impurity concentration is higher or lower, respectively, than layers and regions without + or -. In the description of the embodiments below and the accompanying drawings, main portions that are identical will be given the same reference numerals and are not repeatedly described.

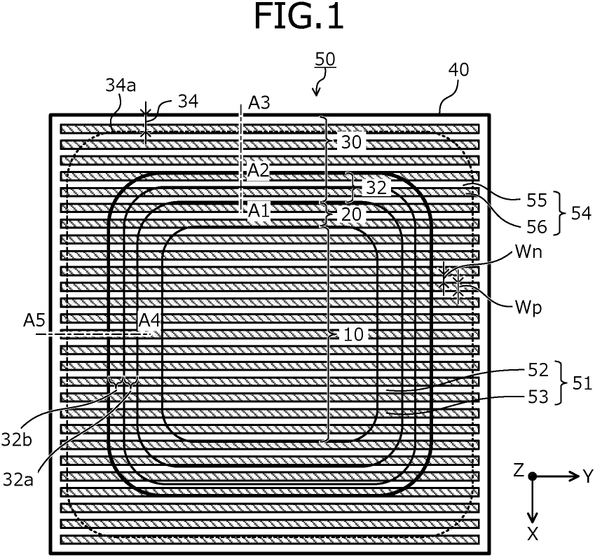

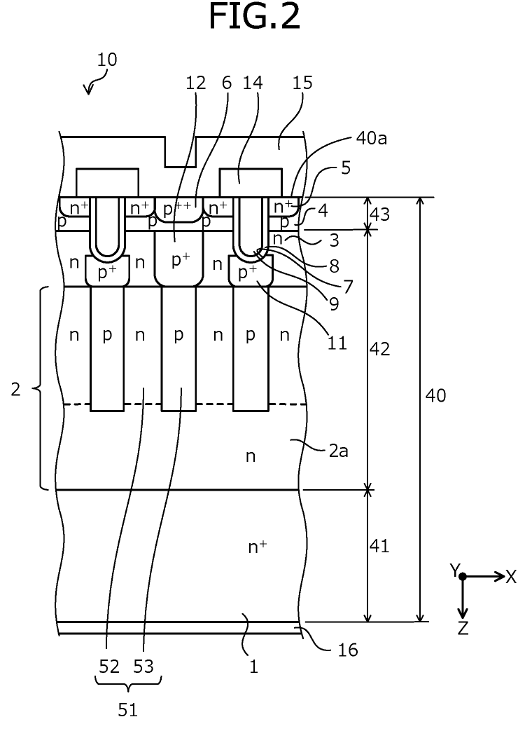

A structure of a silicon carbide semiconductor device according to a first embodiment is described taking a MOSFET as an example. FIG. 1 is a plan view of a layout when the silicon carbide semiconductor device according to the first embodiment is viewed from a front side of a semiconductor substrate thereof. FIG. 1 depicts a layout of a semiconductor substrate 40 that is, for example, a 3 mm² square. In FIG. 1, the number of n-type regions (first and second first-conductivity-type regions) 52, 55 and p-type regions (first and second second-conductivity-type regions) 53, 56 of first and second parallel pn layers 51, 54 is depicted in a simplified manner and differs from the number thereof depicted in FIGS. 2 to 4.

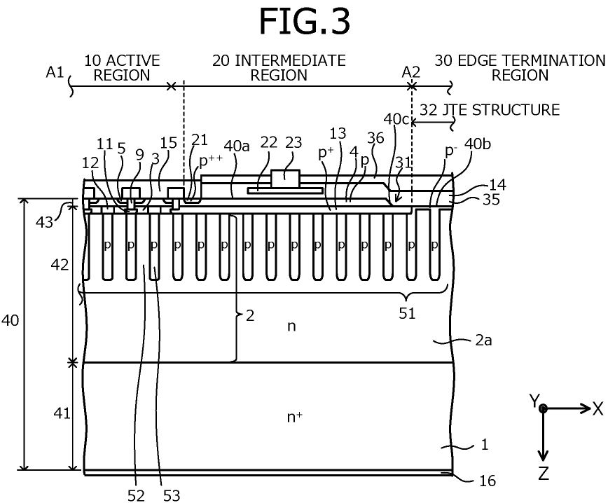

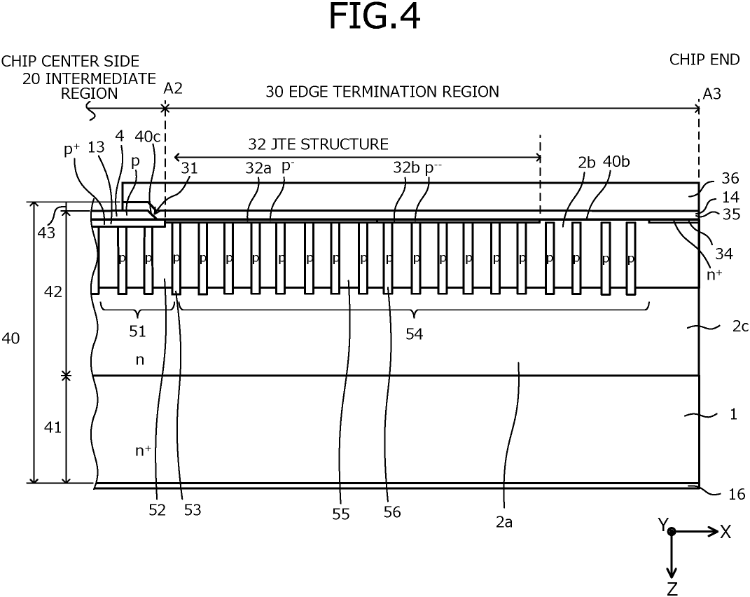

FIG. 2 is a cross-sectional view of the structure of an active region. FIG. 2 depicts one unit cell of multiple unit cells (configuration units of the device) each having the same structure and disposed in an active region 10. FIGS. 3 and 4 are cross-sectional views of the structure along cutting line A1-A2 and cutting line A2-A3 in FIG. 1, respectively. FIG. 3 depicts an area from near a border of an intermediate region 20 to a vicinity of a border between the intermediate region 20 and an edge termination region 30. FIG. 4 depicts an area from near the border between the intermediate region 20 and the edge termination region 30 to an end (chip end) of the semiconductor substrate 40.

A silicon carbide semiconductor device 50 according to the first embodiment depicted in FIGS. 1 to 4 is a vertical MOSFET having the active region 10, the intermediate region 20, and the edge termination region 30 on the semiconductor substrate (semiconductor chip) 40 containing silicon carbide (SiC), as well as a trench gate structure (device structure) with the SJ structure in which, from the active region 10 and spanning to the edge termination region 30, a drift layer (drift region) 2 is configured by parallel pn layers (the first and second parallel pn layers 51, 54). The active region 10 is a region through which a main current flows when the MOSFET is in an on-state and is disposed in a center (chip center) of the semiconductor substrate 40.

The intermediate region 20 is adjacent to the active region 10 and surrounds a periphery of the active region 10. The edge termination region 30 is a region between the intermediate region 20 and the end of the semiconductor substrate 40; and surrounds the periphery of the active region 10 with the intermediate region 20 intervening therebetween. The active region 10 and the intermediate region 20 is a SJ structure in which the drift layer 2 is constituted by the first parallel pn layer 51. The edge termination region 30 is a SJ structure in which the drift layer 2 is constituted by the second parallel pn layer 54.

The border between the active region 10 and the intermediate region 20 is an inner end (inner periphery) of a later-described p⁺⁺-type outer peripheral contact region 21 (refer to FIG. 3) for pulling out minority carriers (holes). The border between the intermediate region 20 and the edge termination region 30 is an inner end (inner periphery) of a later-described JTE structure 32. The inner end of the JTE structure 32 is an inner end of an innermost p-type region (in FIG. 4, a p⁻-type region 32a) of the p-type regions (in FIG. 4, the p⁻-type region 32a and a p⁻⁻-type region 32b that is closer to the chip end than is the p⁻-type region 32a) configuring the JTE structure 32, and is a connecting portion (interface) connecting a later-described p⁺-type outer peripheral region 13 (refer to FIG. 4, second semiconductor region of the second conductivity type) of the intermediate region 20.

The edge termination region 30 has a function of mitigating electric field of the drift layer 2 in the active region 10 and the intermediate region 20, in the front side (side having a first main surface) of the semiconductor substrate 40 and sustaining the breakdown voltage. The breakdown voltage is a voltage limit at which leakage current does not increase excessively and no malfunction or destruction of the device occurs. In the edge termination region 30, the junction termination extension (JTE) structure 32 (first semiconductor region of the second conductivity type) and an n⁺-type channel stopper region 34 are disposed as a voltage withstanding structure. The JTE structure 32 surrounds the periphery of the active region 10 with the intermediate region 20 intervening therebetween.

The JTE structure 32 is a structure in which the p-type regions are disposed adjacent to one another in concentric shapes surrounding the periphery of the active region 10 so as to be in descending order of impurity concentration in a direction from the active region 10 to the chip end, the intermediate region 20 intervening between the JTE structure 32 and the periphery of the active region 10. Concentration of electric field closer to the chip end than is the intermediate region 20 is mitigated by the JTE structure 32 and device destruction due to application of voltage that is less than a predetermined voltage (the breakdown voltage of the edge termination region 30) may be prevented.

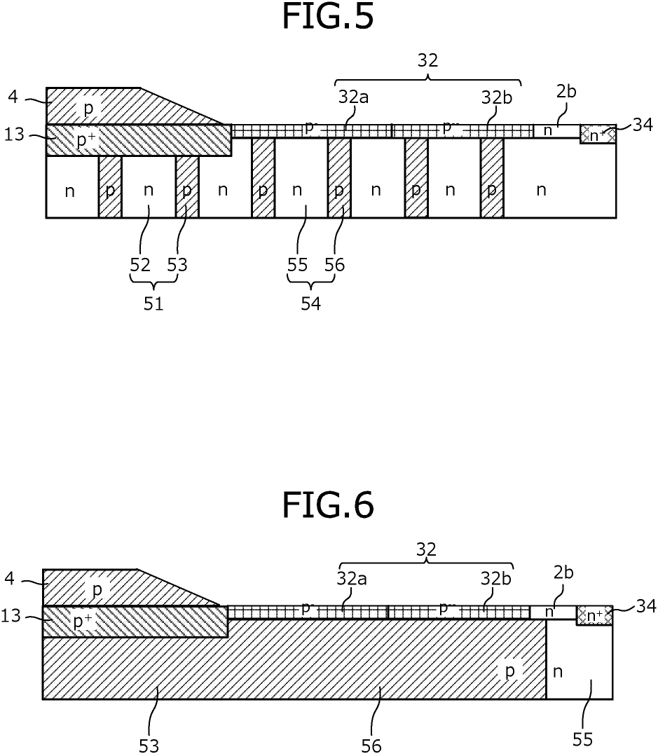

Here, FIGS. 5 and 6 are detailed cross-sectional views of the JTE structure of the silicon carbide semiconductor device according to the first embodiment. FIGS. 5 and 6 are cross-sectional views of the structure along cutting line A2-A3 and cutting line A4-A5 in FIG. 1, respectively. As depicted in FIGS. 5 and 6, the JTE structure 32 of the first embodiment is a structure in which the JTE structure 32 is configured by two p-type regions (the p⁻-type region 32a and the p⁻⁻-type region 32b that is closer to the chip end than is the p⁻-type region 32a) that are adjacent to each other.

In the first embodiment, in an area of the JTE structure 32 where the JTE structure 32 and the p-type regions 56 of the second parallel pn layer 54 overlap each other in a plan view of the semiconductor device, the JTE structure 32 is in direct contact with the p-type regions 56, or between the JTE structure 32 and the p-type regions 56 in a thickness direction, an other p-type region (an other second-conductivity-type region) is provided. The other p-type region is formed, for example, by forming the JTE structure 32 overlapping the p-type regions 56. A thickness (hereinafter, indicated as “overlap depth of the JTE structure 32 and the p-type regions 56”) of the other p-type region is at most 0.1 µm. Here, “at most 0.1 µm” includes an instance in which the JTE structure 32 and the p-type regions 56 of the second parallel pn layer 54 are in contact with each other without overlapping, that is, an instance in which the overlap depth is 0 µm. FIGS. 5 and 6 depict an example in which the overlap depth of the JTE structure 32 and the p-type regions 56 is 0 µm. Further, the p-type regions 56 of the second parallel pn layer and the JTE structure 32 are continuous with each other. As a result, as described in detail hereinafter, when high voltage is applied to the semiconductor device, a depletion layer spreads uniformly in the JTE structure 32 without a neutral region remaining in the JTE structure 32 and a desired breakdown voltage may be sustained. Thus, decreases in the breakdown voltage of the edge termination region 30 may be suppressed.

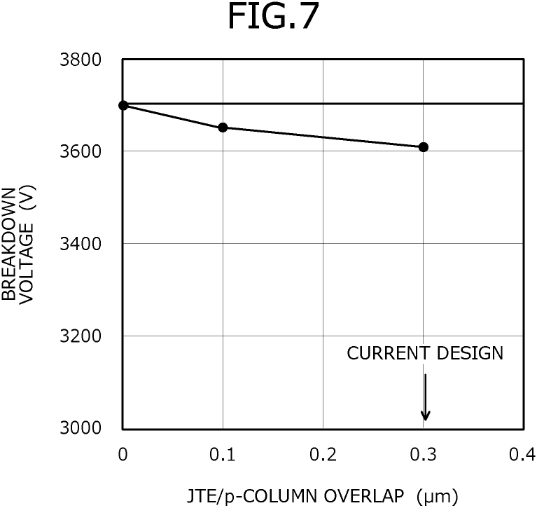

FIG. 7 is a graph depicting results of simulation of the breakdown voltage of the edge termination region of the silicon carbide semiconductor device according to the first embodiment. In FIG. 7, a horizontal axis indicates the overlap depth of the JTE structure 32 and the p-type regions 56 in units of µm. A vertical axis indicates the breakdown voltage of the silicon carbide semiconductor device in units of V. FIG. 7 shows results of simulation when the impurity concentration and the depth of the JTE structure 32 are 1×10¹⁷/cm³ and 0.5 µm, respectively, impurity concentrations of the p-type regions 56 and the n-type regions 55 are 3×10¹⁶/cm³ and 7×10¹⁶ /cm³ while the widths Wn, Wp thereof are 3.5 µm and 1.5 µm, respectively, and an upper limit of the breakdown voltage is 3700 V.

As depicted in FIG. 7, as the extent to which the p-type regions 56 and the JTE structure 32 overlap increases, the breakdown voltage tends to decrease. Furthermore, in regions where the p-type regions 56 and the JTE structure 32 overlap, spreading of the depletion layer is inhibited and thus, as the thickness of the p-type regions 56 increases, the overlap depth is thought to have a greater effect on the decline of the breakdown voltage. In the conventional silicon carbide semiconductor device, the overlap depth of the JTE structure 32 and the p-type regions 56 is about 0.3 µm. Decrease of the breakdown voltage is within 1.5%, in other words, to set the breakdown voltage to be about 3650V or greater, preferably, the overlap depth of the JTE structure 32 and the p-type regions 56 may be 0.1 µm or less.

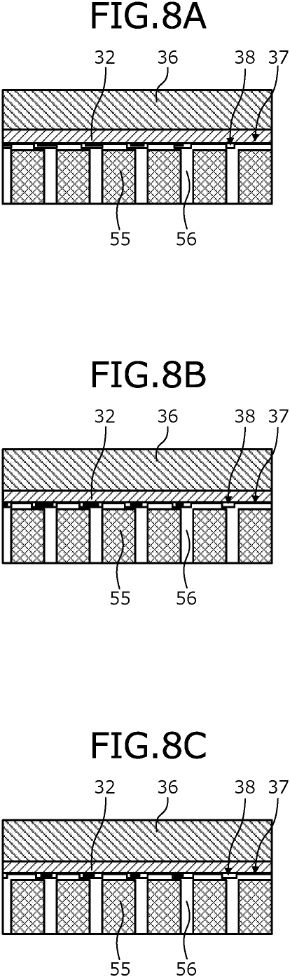

FIGS. 8A, 8B, and 8C are figures showing results of simulation of depletion layer distribution of the silicon carbide semiconductor device according to the first embodiment. FIGS. 8A, 8B, and 8C show results for instances in which the overlap depth of the JTE structure 32 and the p-type regions 56 is 0 µm, 0.1 µm, and 0.3 µm, respectively. FIGS. 8A to 8C show the depletion layer distribution for Vds=3700V.

As depicted in FIGS. 8A to 8C, when high voltage is applied between a drain and source, a depletion layer 37 is formed in the JTE structure 32; however, spreading of the depletion layer in the regions where the JTE structure 32 and the p-type regions 56 overlap is inhibited and a neutral region 38 that is not depleted is present. The neutral region 38 becomes larger as the overlap depth increases.

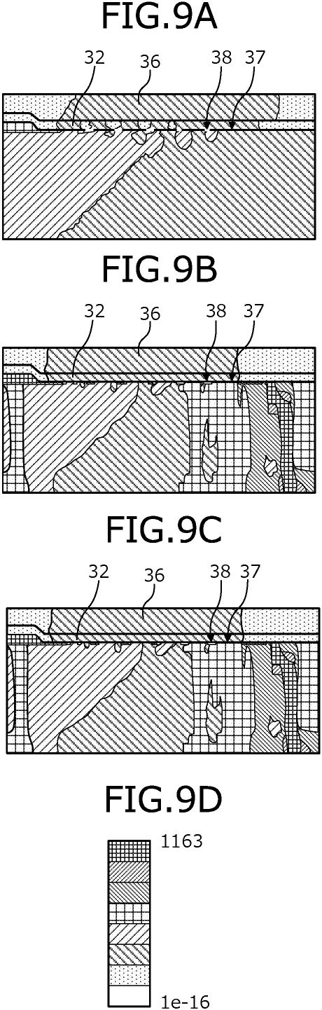

Further, FIGS. 9A, 9B, and 9C are figures depicting results of simulation of current density distribution of the silicon carbide semiconductor device according to the first embodiment. FIG. 9D is a figure showing current density values in FIGS. 9A to 9C. In FIG. 9D, the unit is A/cm². FIGS. 9A, 9B, and 9C each show results in instances in which the overlap depth of the JTE structure 32 and the p-type regions 56 are 0 µm, 0.1µpm, and 0.3 µm, respectively. FIGS. 9A to 9C show current density distribution for Vds=3700 V.

As depicted in FIGS. 9A to 9C, it is found that when high voltage is applied between the drain and source, a portion where current density is high at the chip end becomes larger as the overlap depth increases and the breakdown voltage decreases.

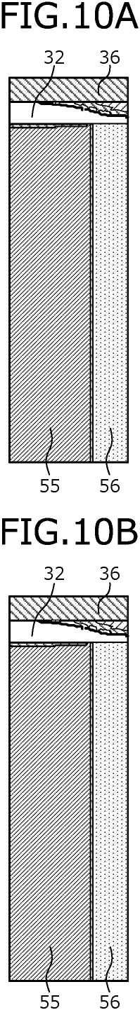

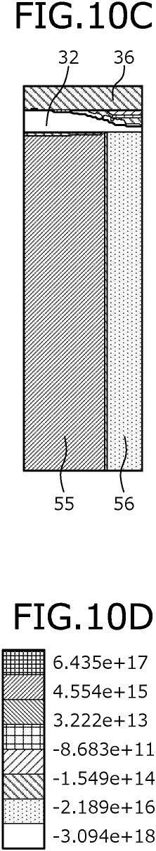

Further, FIGS. 10A, 10B, and 10C are figures showing results of simulation of space charge distribution for the silicon carbide semiconductor device according to the first embodiment. FIG. 10D is a figure showing values of the space charge in FIGS. 10A to 10C. In FIG. 10D, the unit is /cm³. FIGS. 10A, 10B, and 10C show results in instances in which the overlap depth of the JTE structure 32 and the p-type regions 56 is 0.1 µm, 0.2 µm, 0.3 µm, respectively. FIGS. 10A to 10C show space charge distribution for Vds=3500 V.

As depicted in FIGS. 10A to 10C, when high voltage is applied between the drain and source, the value of the space charge in the regions where the JTE structure 32 and the p-type regions 56 overlap increases as the overlap depth increases. In the regions where the JTE structure 32 and the p-type regions 56 overlap, the neutral region 38 is present and the neutral region 38 becomes larger as the overlap depth increases, whereby the space charge increases.

From the simulation results above, it is found that in regions where the JTE structure 32 and the p-type regions 56 overlap, the p-type impurity concentration increases, depletion of the JTE structure 32 above the p-type regions 56 becomes difficult, and many neutral regions are left. As a result, the neutral regions form a path of leakage current and the breakdown voltage decreases. Thus, as described above, in the first embodiment, the overlap depth of the JTE structure 32 and the p-type regions 56 is set to be 0.1 µm or less. From the simulation results, it is found that while an instance in which the JTE structure 32 and the p-type regions 56 are in contact with each other without overlap is most desirable, when the overlap depth is set to 0 µm, gaps may occur between the JTE structure 32 and the p-type regions 56 due to dimensional deviation during manufacture and therefore, the overlap depth is set as 0.1 µm or less.

The n⁺-type channel stopper region 34 is disposed apart from the JTE structure 32 and closer to the chip end than is the JTE structure 32, reaching, for example, the end of the semiconductor substrate 40, at the four edges (straight portions) of the end of the semiconductor substrate 40. The n⁺-type channel stopper region 34 extends along the end of the semiconductor substrate 40 and thereby surrounds a periphery of the JTE structure 32. In FIG. 1, an inner periphery of the n⁺-type channel stopper region 34 is indicated by a dashed line 34a. The n⁺-type channel stopper region 34 is provided in an entire area from the dashed line 34a to the chip end and an outer periphery of the n⁺-type channel stopper region 34 is the end of the semiconductor substrate 40, which has a substantially rectangular shape in a plan view.

The first parallel pn layer 51 is a SJ structure in which the n-type regions 52 and the p-type regions 53 are disposed adjacent to one another so as to repeatedly alternate with one another in the first direction X, which is parallel to a front surface of the semiconductor substrate 40. The n-type regions 52 and the p-type regions 53 of the first parallel pn layer 51 extend to a vicinity of an end of the intermediate region 20, in a striped pattern in the second direction Y, which is parallel to the front surface of the semiconductor substrate 40 and orthogonal to the first direction X.

Further, the first parallel pn layer 51 is provided in the first direction X, in the active region 10 and the intermediate region 20. Thus, a border between the first parallel pn layer 51 and the second parallel pn layer 54 is positioned at the end of the intermediate region 20. The first parallel pn layer 51 has the n-type regions 52 and the p-type regions 53 that pass through the active region 10 and the intermediate region 20.

The n-type regions 52 and the p-type regions 53 of the first parallel pn layer 51 are in contact with the p⁺-type outer peripheral region 13 of the intermediate region 20, in the depth direction Z. The p-type regions 53 of the first parallel pn layer 51 is fixed to a potential of a source electrode (first electrode) 15 (refer to FIGS. 2 and 3), via the p⁺-type outer peripheral region 13.

The n-type regions 52 and the p-type regions 53 that are adjacent to one another in the first parallel pn layer 51 are roughly charge balanced with each other. Being charge balanced means that an amount of charge expressed by a product obtained by multiplying the carrier concentration (impurity concentration) and width of the n-type regions of the parallel pn layer and an amount of charge expressed by a product obtained by multiplying the carrier concentration and width of the p-type regions of the parallel pn layer are substantially the same within a range that includes an allowable error due to process variation. Thus, the carrier concentrations and the widths (widths in the first direction X) Wn, Wp of the n-type regions 52 and the p-type regions 53 are each set so that the n-type regions 52 and the p-type regions 53 that are adjacent to one another in the first parallel pn layer 51 are roughly charge balanced.

The n-type regions 52 and the p-type regions 53 that are adjacent to one another in the first parallel pn layer 51 suffice to be roughly charge balanced and the carrier concentrations and the widths Wn, Wp of the n-type regions 52 and the p-type regions 53 of the first parallel pn layer 51 are each suitably set. For example, the width Wn of the n-type regions 52 of the first parallel pn layer 51 and the width Wp of the p-type regions 53 of the first parallel pn layer 51 may be substantially the same. In this instance, the carrier concentration of the n-type regions 52 and the carrier concentration of the p-type regions 53 may be set to be substantially the same. The widths and the carrier concentrations being substantially the same means that each are the same width and the same carrier concentration within respective ranges that include an allowable error due to process variation.

The second parallel pn layer 54 is a SJ structure in which the n-type regions 55 and the p-type regions 56 are disposed adjacent to one another so as to repeatedly alternate with one another in the first direction X, which is parallel to the front surface of the semiconductor substrate 40. The n-type regions 55 and the p-type regions 56 of the second parallel pn layer 54 extend in a striped pattern parallel to the n-type regions 52 and the p-type regions 53 of the first parallel pn layer 51, in the second direction Y. The second parallel pn layer 54 is connected to both sides of the first parallel pn layer 51 in the second direction Y, in the active region 10 and the intermediate region 20; and is disposed only in the edge termination region 30. The second parallel pn layer 54 is adjacent to both sides of the first parallel pn layer 51, in the first direction X and is disposed only in the edge termination region 30. The second parallel pn layer 54 is disposed so that the n-type regions 55 are adjacent to an outermost one of the p-type regions 53 of the first parallel pn layer 51 in the first direction X and closer to the chip end than is the outermost one in the first direction X. Further, the second parallel pn layer 54 is disposed closer to the chip end than is an outer end of the JTE structure 32 in the first direction X so that at least one of the p-type regions 56 is disposed closer to the chip end in the first direction X than is an outer end (outer periphery) of the JTE structure 32.

The p-type regions 56 of the second parallel pn layer 54 are disposed closer to the chip end than is the outer end of the JTE structure 32 in the first direction X, whereby when the MOSFET is off, concentration of electric field at the outer end of the JTE structure 32 may be suppressed. The outer end of the JTE structure 32 is an outer end of an innermost one of the p-type regions that configure the JTE structure 32. Further, the second parallel pn layer 54 may be disposed up to a range of, for example, about 10 µm or less from the outer end of the JTE structure 32 in the first direction X.

The range in which the second parallel pn layer 54 is disposed is set within the above range from the outer end of the JTE structure 32 in the first direction X, and the number of the p-type regions 56 that are floating and disposed in the edge termination region 30 is reduced. As a result, charge due to MOSFET switching, etc. is stored in the edge termination region 30 and the amount of charge of remaining minority carriers (holes) not discharged externally may be reduced. Thus, the number of the p-type regions 56 disposed closer to the chip end than is the outer end of the JTE structure 32 in the first direction X may be preferably fewer.

Provided the second parallel pn layer 54 is within the above range from the outer end of the JTE structure 32 in the first direction X, the second parallel pn layer 54 may be disposed in the first direction X to a portion directly beneath the n⁺-type channel stopper region 34 (side thereof facing an n⁺-type drain region 1). In the first direction X, between the second parallel pn layer 54 and the end of the semiconductor substrate 40, a later-described normal n⁻-type drift region 2b (refer to FIG. 4) may be provided. The semiconductor substrate 40 may be reduced in size by omitting the normal n⁻-type drift region 2b or may be reduced in size to an extent that the width of the normal n⁻-type drift region 2b is reduced.

The n-type regions 55 and the p-type regions 56 of the second parallel pn layer 54 are in contact with the JTE structure 32 in the depth direction Z. The p-type regions 56 of the second parallel pn layer 54 are fixed to the potential of the source electrode 15 via the p⁺-type outer peripheral region 13 that is in contact with the JTE structure 32 (refer to FIGS. 2 and 3).

The n-type regions 55 and the p-type regions 56 that are adjacent to one another in the second parallel pn layer 54 are roughly charge balanced. The carrier concentrations and the widths (widths in the first direction X) Wn, Wp of the n-type regions 55 and the p-type regions 56 are each set so that charge balance is achieved by the n-type regions 55 and the p-type regions 56 that are adjacent to one another in the second parallel pn layer 54. The n-type regions 55 and the p-type regions 56 that are adjacent to one another in the second parallel pn layer 54 suffice to be roughly charge balanced and the carrier concentrations and the widths Wn, Wp of the n-type regions 55 and the p-type regions 56 of the second parallel pn layer 54 are suitably set. For example, in the second parallel pn layer 54, the width Wn of the n-type regions 55 and the width Wp of the p-type regions 56 may be substantially the same. In this case, the carrier concentration of the n-type regions 55 and the carrier concentration of the p-type regions 56 suffice to be set to be substantially the same.

A cross-section of the structure of the silicon carbide semiconductor device 50 according to the first embodiment is described. As depicted in FIG. 2, in the active region 10, a general trench gate structure is provided in the front side of the semiconductor substrate 40. The trench gate structure is configured by a p-type base region 4, n⁺-type source regions 5, p⁺⁺-type contact regions 6, gate trenches 7, gate insulating films 8, and gate electrodes 9. The semiconductor substrate 40 is formed by sequentially depositing epitaxial layers 42, 43 constituting the drift layer 2 and the p-type base region 4 on a front surface of an n⁺-type starting substrate 41 containing silicon carbide.

The semiconductor substrate 40 has, as the front surface, a main surface having the p-type epitaxial layer 43 and has, as a back surface (second main surface), a main surface having the n⁺-type starting substrate 41. The n⁺-type starting substrate 41 constitutes the n⁺-type drain region 1. A portion of the p-type epitaxial layer 43 at least in the edge termination region 30 is removed by etching, thereby forming a drop 31 at the front surface of the semiconductor substrate 40. The front surface of the semiconductor substrate 40 has a portion (first portion) 40a in the active region 10 and a portion (second portion) 40b in the edge termination region 30 separated from each other by the drop 31, the second portion 40b being recessed toward the n⁺-type drain region 1 as compared to the first portion 40a.

The second portion 40b of the front surface of the semiconductor substrate 40 is an exposed surface of the n⁻-type epitaxial layer 42 that is exposed by the removal of the p-type epitaxial layer 43. Devices of the active region 10 and the intermediate region 20 are isolated from those of the edge termination region 30 by a portion (third portion: mesa edge of the drop 31) 40c of the front surface of the semiconductor substrate 40, connecting the first portion 40a and the second portion 40b. The gate trenches 7 penetrate through the p-type epitaxial layer 43 in the depth direction Z from the first portion 40a of the front surface of the semiconductor substrate 40 and reach the n⁻-type epitaxial layer 42.

The gate trenches 7, for example, extend in a striped pattern in a direction (herein, the second direction Y) parallel to the front surface of the semiconductor substrate 40. In the gate trenches 7, the gate electrodes 9 are provided via the gate insulating films 8, respectively. The p-type base region 4, the n⁺-type source regions 5, and the p⁺⁺-type contact regions 6 are selectively provided between the gate trenches 7 that are adjacent to one another. The p-type base region 4 is a portion of the p-type epitaxial layer 43, excluding the n⁺-type source regions 5 and the p⁺⁺-type contact regions 6.

The p-type base region 4 extends from the active region 10 in a direction to the chip end and reaches the third portion 40c of the front surface of the semiconductor substrate 40. Between the first portion 40a of the front surface of the semiconductor substrate 40 and the p-type base region 4, the n⁺-type source regions 5 and the p⁺⁺-type contact regions 6 are selectively provided in contact with the p-type base region 4 and are exposed at the first portion 40a of the front surface of the semiconductor substrate 40. Being exposed at the first portion 40a of the front surface of the semiconductor substrate 40 means being in contact with the source electrode 15 in contact holes of an interlayer insulating film 14.

The p⁺⁺-type contact regions 6 are disposed farther from the gate trenches 7 than are the n⁺-type source regions 5. A portion of the n⁻-type epitaxial layer 42, excluding a later-described n-type current spreading region 3, p⁺-type regions 11, 12, the p⁺-type outer peripheral region 13, the p⁻-type region 32a, the p⁻⁻-type region 32b, and the n⁺-type channel stopper region 34, is the drift layer 2, which functions as a drift region of the MOSFET, and includes the first and second parallel pn layers 51, 54. In the drift layer 2, a portion thereof between the n⁺-type starting substrate 41 and the first and second parallel pn layers 51, 54 may be a normal n-type drift region 2a that is not the SJ structure.

The first and second parallel pn layers 51, 54 are disposed at the predetermined positions described above in the n⁻-type epitaxial layer 42. The first and second parallel pn layers 51, 54, for example, are formed using a multistage epitaxial method in which, regions respectively constituting the n-type regions 52, 55 and the p-type regions 53, 56 are selectively formed by ion implantation so that in sublayers of the n⁻-type epitaxial layer 42 epitaxially grown at each of the multiple stages into which the epitaxial growth of the n⁻-type epitaxial layer 42 constituting the drift layer 2 is divided, regions of the same conductivity type are in contact with one another in the depth direction Z.

Further, the first and second parallel pn layers 51, 54, for example, may be formed using a trench embedding epitaxial method in which trenches (hereinafter, SJ trenches) are formed in an n-type epitaxial layer, leaving portions of the n-type epitaxial layer constituting the n-type regions 52, 55, and embedding the SJ trenches with a p-type epitaxial layer that constitutes the p-type regions 53, 56.

In the active region 10, between the p-type base region 4 and the first parallel pn layer 51 (the drift layer 2), the n-type current spreading region 3 and the p⁺-type regions 11, 12 are each selectively provided. The n-type current spreading region 3 and the p⁺-type regions 11, 12, for example, are spreading regions formed by ion implantation in the n⁻-type epitaxial layer 42. The n-type current spreading region 3 and the p⁺-type regions 11, 12 are disposed at deep positions closer to the n⁺-type drain region 1 than are bottoms of the gate trenches 7, and extend linearly in the second direction Y, parallel to the gate trenches 7.

The n-type current spreading region 3 is a so-called current spreading layer (CSL) that reduces carrier spreading resistance. Between the gate trenches 7 that are adjacent to one another, the n-type current spreading region 3 is in contact with the p⁺-type regions 11, 12, the p-type base region 4, and the n-type regions 52 of the first parallel pn layer 51, and reaches a deep position closer to the n⁺-type drain region 1 than are the bottoms of the gate trenches 7. Instead of the n-type current spreading region 3, a portion of the n⁻-type epitaxial layer 42 free of ion implantation may be disposed.

The p⁺-type regions 11, 12 have a function of mitigating electric field applied to the bottoms of the gate trenches 7. The p⁺-type regions 11, 12 are in contact with respectively different the p-type regions 53 of the first parallel pn layer 51 in the depth direction Z. The p⁺-type regions 11 are disposed apart from the p-type base region 4 and face in the bottoms of the gate trenches 7, respectively, in the depth direction Z. Between the gate trenches 7 that are adjacent to one another, the p⁺-type regions 12 are provided in contact with the p-type base region 4 and apart from the p⁺-type regions 11 and the gate trenches 7.

The interlayer insulating film 14 covers an entire area of the front surface of the semiconductor substrate 40 except for contact portions of the active region 10 and a later-described outer-peripheral contact portion of the intermediate region 20. The contact portions of the active region 10 are ohmic contact portions between the source electrode 15 and the n⁺-type source regions 5 and the p⁺⁺-type contact regions 6. The outer-peripheral contact portion of the intermediate region 20 is an ohmic contact portion between the source electrode 15 and the later-described p⁺⁺-type outer peripheral contact region 21 (in an instance in which the p⁺⁺-type outer peripheral contact region 21 is omitted, the p-type base region 4).

In the intermediate region 20, in the front surface side of the semiconductor substrate 40, the p-type base region 4 and an outermost one of the p⁺-type regions 11 (hereinafter, the p⁺-type outer peripheral region 13) facing the bottom of an outermost one of the gate trenches 7 in the first direction X extend from the active region 10. The p-type base region 4 of the intermediate region 20 surrounds the periphery of the active region 10. In the intermediate region 20, between the first portion 40a of the front surface of the semiconductor substrate 40 and the p-type base region 4, a p⁺⁺-type contact region (hereinafter, the p⁺⁺-type outer peripheral contact region 21) is selectively provided.

The p⁺⁺-type outer peripheral contact region 21 is an outer-peripheral contact portion that is in contact with the source electrode 15 and for pulling out minority carriers (holes) accumulated in the edge termination region 30 due to switching of the MOSFET, to the source electrode 15 via the p⁺-type outer peripheral region 13 and the p-type base region 4 when the MOSFET is off. The p⁺⁺-type outer peripheral contact region 21 surrounds the periphery of the active region 10. The p⁺⁺-type outer peripheral contact region 21 is in ohmic contact with a portion of the source electrode 15 extending into the intermediate region.

The p⁺-type outer peripheral region 13 extends along the border between the active region 10 and the intermediate region 20 and surrounds the periphery of the active region 10. Ends of all the p⁺-type regions 11, 12 of the active region 10 are connected to the p⁺-type outer peripheral region 13. Further, the p⁺-type outer peripheral region 13 extends toward the chip end from the drop 31 of the front surface of the semiconductor substrate 40, and is exposed at the second portion 40b of the front surface of the semiconductor substrate. Being exposed at the second portion 40b of the front surface of the semiconductor substrate 40 means being in contact with a later-described field oxide film 35 on the second portion 40b.

In the intermediate region 20 and the edge termination region 30, on the front surface of the semiconductor substrate 40, in an entire area closer to the chip end than is the p⁺⁺-type outer peripheral contact region 21, an insulating layer in which the field oxide film 35 and the interlayer insulating film 14 are sequentially stacked is provided. In the intermediate region 20, on the field oxide film 35, closer to the chip end than is the p⁺⁺-type outer peripheral contact region 21, a polysilicon (poly-Si) layer 22 that constitutes a gate runner that electrically connects the gate electrodes 9 and a gate pad (not depicted), and a metal wiring layer 23 are sequentially stacked.

In the semiconductor substrate 40, at the second portion 40b of the front surface thereof, the p-type regions that configure the JTE structure 32 are selectively provided in the n⁻-type epitaxial layer 42, and the n⁺-type channel stopper region 34 is selectively provided apart from and closer to the chip end than is the JTE structure 32. Of the p-type regions that configure the JTE structure 32, an innermost one of the p-type regions is in contact with the p⁺-type outer peripheral region 13 in a direction parallel to the front surface of the semiconductor substrate 40. The p-type regions that configure the JTE structure 32 are fixed to the potential of the source electrode 15 via the p⁺-type outer peripheral region 13.

Between the JTE structure 32 and the n⁺-type channel stopper region 34 is the normal n⁻-type drift region 2b that is not the SJ structure. The p-type regions (the p⁻-type region 32a, the p⁻⁻-type region 32b) that configure the JTE structure 32 and the n⁺-type channel stopper region 34 are diffused regions formed by ion implantation in the n⁻-type epitaxial layer 42 and are exposed at the second portion 40b of the front surface of the semiconductor substrate 40. In the n⁻-type epitaxial layer 42, a portion thereof at the surface of the n⁻-type epitaxial layer 42 and free of ion implantation is the normal n⁻-type drift region 2b and is exposed at the second portion 40b of the front surface of the semiconductor substrate 40.

In the intermediate region 20, the n-type regions 52 and the p-type regions 53 of the first parallel pn layer 51 are adjacent to the p⁺-type outer peripheral region 13 in the depth direction Z. The n-type regions 55 and the p-type regions 56 of the second parallel pn layer 54 face the p⁻-type region 32a and the p⁻-type region 32b of the JTE structure 32 in the depth direction Z. In the edge termination region 30, the n-type regions 55 and the p-type regions 56 of the second parallel pn layer 54 are adjacent to the p⁺-type outer peripheral region 13 in the depth direction Z.

Between the second parallel pn layer 54 and the p⁻-type region 32a and the p⁻-type region 32b of the JTE structure 32 is the normal n⁻-type drift region 2b that is not the SJ structure. A normal n⁻-type drift region 2c that is not the SJ structure may be disposed between the second parallel pn layer 54 and the end of the semiconductor substrate 40. The normal n⁻-type drift region 2c is a portion of the n⁻-type epitaxial layer 42, a portion that is left free of ion implantation between the second parallel pn layer 54 and the end of the semiconductor substrate 40.

The second and third portions 40b, 40c of the front surface of the semiconductor substrate 40, as described above, are covered by the insulating layer in which the field oxide film 35 and the interlayer insulating film 14 are sequentially stacked. A passivation film 36 covers an entire area of the front surface of the semiconductor substrate 40 and protects the front surface of the semiconductor substrate 40. A portion of the source electrode 15 exposed from an opening in the passivation film 36 functions as a source pad. In an entire area of the back surface (back surface of the n⁺-type starting substrate 41) of the semiconductor substrate 40, a drain electrode (second electrode) 16 is provided.

Next, a method of manufacturing the silicon carbide semiconductor device 50 according to the first embodiment is described. First, the drift layer 2 having the first and second parallel pn layers 51, 54 is formed on the front surface of the n⁺-type starting substrate (semiconductor wafer) 41 constituting the n⁺-type drain region 1. For example, in an instance in which the multistage epitaxial method is used, regions constituting the n-type regions 52, 55 and the p-type regions 53, 56 are each selectively formed by ion implantation so that in sublayers of the n⁻-type epitaxial layer 42 epitaxially grown at each of the multiple stages (for example, 9 stages) into which the epitaxial growth of the n⁻-type epitaxial layer 42 constituting the drift layer 2 is divided, regions of the same conductivity type are in contact with one another in the depth direction Z.

Further, the n-type current spreading region 3, the p⁺-type regions 11, 12, and the p⁺-type outer peripheral region 13 are formed in surface regions of the first parallel pn layer 51 by ion implantation. In the active region 10 and the intermediate region, in the uppermost stage of the n⁻-type epitaxial layer 42, the n-type current spreading region 3, the p⁺-type regions 11, 12, and the p⁺-type outer peripheral region 13 may be formed without forming the first parallel pn layer 51. The n-type current spreading region 3, the p⁺-type regions 12, and the p⁺-type outer peripheral region 13 may be divided into two stages of upper portions and lower portions formed respectively with epitaxial growth sessions of the n⁻-type epitaxial layer 42; and the p⁺-type regions 11 may be formed concurrently with the lower portions of the p⁺-type regions 12 and the p⁺-type outer peripheral region 13.

Next, on the n⁻-type epitaxial layer 42, the p-type epitaxial layer 43 constituting the p-type base region 4 is epitaxially grown. As a result, the semiconductor substrate (the semiconductor wafer) 40 is fabricated in which the epitaxial layers 42, 43 are sequentially stacked on the n⁺-type starting substrate 41, and in the n⁻-type epitaxial layer 42, the first and second parallel pn layers 51, 54 are included. Next, a portion of the p-type epitaxial layer 43 at least in the edge termination region 30 is removed by etching, thereby, forming at the front surface of the semiconductor substrate 40, the drop 31 that recesses a portion (the second portion 40b) that is closer to the chip end than is the active region 10, to be closer to the n⁺-type starting substrate 41 than is a portion (the first portion 40a) that is closer to the active region 10 than is the recessed portion (refer to FIGS. 3 and 4).

In the edge termination region 30, at the newly formed second portion 40b of the front surface of the semiconductor substrate 40, the n-type current spreading region (third semiconductor region of the first conductivity type) 3 is exposed. A portion (the third portion 40c) between the first portion 40a and the second portion 40b of the front surface of the semiconductor substrate 40, for example, may form an obtuse angle with the first and second portions 40a, 40b (sloped surface), or may form a substantially right angle (vertical surface). At the second and third portions 40b, 40c of the front surface of the semiconductor substrate 40, the p-type base region 4 and the p⁺-type outer peripheral region 13 are exposed. At an edge formed by the drop 31, the p-type epitaxial layer 43 is completely removed while the n-type current spreading region 3 is partially removed and left having a thickness equivalent to that of the thickness of the JTE structure 32.

Next, by ion implantation, the n⁺-type source regions 5, the p⁺⁺-type contact regions 6, the p⁺⁺-type outer peripheral contact region 21, the p-type regions (the p⁻-type region 32a, the p⁻-type region 32b) of the JTE structure 32, and the n⁺-type channel stopper region 34 are each selectively formed. The n⁺-type source regions 5, the p⁺⁺-type contact regions 6, and the p⁺⁺-type outer peripheral contact region 21 are each formed in surface regions of the p-type epitaxial layer 43. A portion of the p-type epitaxial layer 43, excluding the n⁺-type source regions 5, the p⁺⁺-type contact regions 6, and the p⁺⁺-type outer peripheral contact region 21, constitutes the p-type base region 4.

The p⁻-type region 32a and the p⁻-type region 32b of the JTE structure 32 and the n⁺-type channel stopper region 34 are each selectively formed in surface regions of the n-type current spreading region 3 exposed at the second portion 40b of the front surface of the semiconductor substrate 40, in the edge termination region 30. A sequence in which the n⁺-type source regions 5, the p⁺⁺-type contact regions 6, the p⁺⁺-type outer peripheral contact region 21, the p-type regions (the p⁻-type region 32a, the p⁻⁻-type region 32b) of the JTE structure 32, and the n⁺-type channel stopper region 34 are formed may be interchanged. Before the formation of the drop 31, the n⁺-type source regions 5, the p⁺⁺-type contact regions 6, and the p⁺⁺-type outer peripheral contact region 21 may be formed.

In this manner, in the first embodiment, the n-type current spreading region 3 is etched so that the thickness thereof is the same as that of the JTE structure 32, whereby the p-type regions 52 and the JTE structure 32 are formed to be in contact with each other, eliminating overlap therebetween.

Next, a heat treatment (hereinafter, activation annealing) for activating the impurities ion-implanted into the epitaxial layers 42, 43 is performed. Next, the gate trenches 7 that penetrate through the n⁺-type source regions 5 and the p-type base region 4 from the front surface of the semiconductor substrate 40 and face the p⁺-type regions 11 are formed in the n-type current spreading region 3. Next, along the front surface of the semiconductor substrate 40 and inner walls of the gate trenches 7, the gate insulating films 8 are formed. Next, a polysilicon layer deposited on the front surface of the semiconductor substrate 40 so as to be embedded in the gate trenches 7 is etched and portions thereof constituting the gate electrodes 9 are left in the gate trenches 7.

In the intermediate region 20 and the edge termination region 30, the field oxide film 35 is formed at the front surface of the semiconductor substrate 40. In the intermediate region 20, the polysilicon layer 22 constituting the gate runner is formed on the field oxide film 35. The polysilicon layer 22 may be formed by a portion of the polysilicon layer deposited on the front surface of the semiconductor substrate 40 when the gate electrodes 9 are formed. Next, the interlayer insulating film 14 is formed in an entire area of the front surface of the semiconductor substrate 40. Next, by a general method, surface electrodes (the source electrode 15, the gate pad, the metal wiring layer 23, and the drain electrode 16) are formed at the main surfaces of the semiconductor substrate 40.

Next, a portion of the front surface of the semiconductor substrate 40, excluding a portion (portion becoming the source pad) of the source electrode 15, the gate pad, and the metal wiring layer 23, is covered and protected by the passivation film 36. Thereafter, the semiconductor wafer (the semiconductor substrate 40) is diced (cut) into individual chips, whereby, the silicon carbide semiconductor device 50 depicted in FIGS. 1 to 4 is completed.

As described above, according to the first embodiment, the thickness of a region where the JTE structure and the p-type regions of the second parallel pn layer overlap is 0.1 µm or less. As a result, when high voltage is applied to the semiconductor device, a depletion region may uniformly spread in the JTE structure without leaving neutral regions in the JTE structure and the desired breakdown voltage may be sustained. Thus, decreases in the breakdown voltage of the edge termination region may be suppressed.

Further, at the front surface of the semiconductor substrate, when the drop is formed that recesses the portion of the front surface closer to the chip end, to be closer to the starting substrate than is a portion that is closer to the active region than is the recessed portion, the thickness of the n-type current spreading region is etched to have the same thickness as that of the JTE structure, whereby the p-type regions and the JTE structure may be formed to be in contact with each other without overlapping.

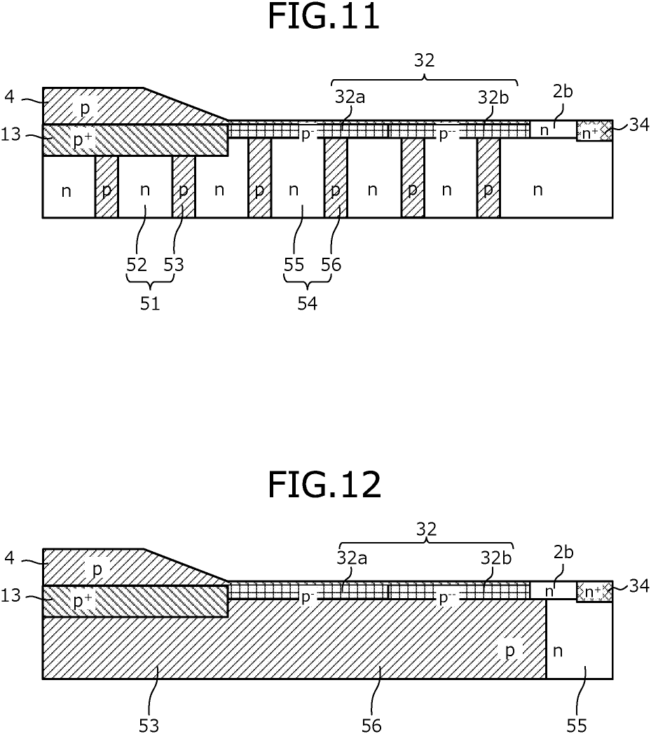

Next, a structure of a silicon carbide semiconductor device according to a second embodiment is described. FIGS. 11 and 12 are detailed cross-sectional views of the JTE structure of the silicon carbide semiconductor device according to the second embodiment. A layout when the silicon carbide semiconductor device according to the second embodiment is viewed from the front side of the semiconductor substrate thereof and a cross-sectional view of the structure in the active region are the same as those of the first embodiment and thus, description thereof is omitted hereinafter (refer to FIGS. 1 and 2). FIGS. 11 and 12 are cross-sectional views of the structure along cutting line A2-A3 and cutting line A4-A5 in FIG. 1, respectively.

In the silicon carbide semiconductor device according to the second embodiment, similarly to the first embodiment, the thickness of the region where the JTE structure 32 and the p-type regions 56 of the second parallel pn layer 54 overlap is 0.1 µm or less. FIGS. 11 and 12 depict an example in which the overlap depth of the JTE structure 32 and the p-type regions 56 is 0 µm. In the second embodiment, a first surface of the JTE structure 32, opposite to a second surface thereof facing the second parallel pn layer 54, extends beyond (in a direction toward the passivation film 36 and the source electrode 15) a first surface of the p⁺-type outer peripheral region 13, opposite to a second surface thereof facing the first parallel pn layer 51. The n⁺-type channel stopper region 34 and the n⁻-type drift region 2b, which is between the n⁺-type channel stopper region 34 and the JTE structure 32, each has a first surface that is opposite to a second surface thereof facing the second parallel pn layer 54 and that similarly, extends beyond the first surface of the p⁺-type outer peripheral region 13, opposite to the second surface thereof facing the first parallel pn layer 51 and has a same height as that of the JTE structure 32.

Next, a method of manufacturing the silicon carbide semiconductor device according to the second embodiment is described. FIG. 13 is a cross-sectional view of a state of the JTE structure of the silicon carbide semiconductor device according to the second embodiment during manufacture. In the second embodiment, similarly to the first embodiment, the semiconductor substrate (the semiconductor wafer) 40 is fabricated in which the epitaxial layers 42, 43 are sequentially stacked on the n⁺-type starting substrate 4 and the first and second parallel pn layers 51, 54 are included in the epitaxial layer 42. Next, a portion of the p-type epitaxial layer 43 at least in the edge termination region 30 is removed by etching, thereby, forming at the front surface of the semiconductor substrate 40, the drop 31 that recesses a portion (the second portion 40b) that is closer to the chip end than is the active region 10, to be closer to the n⁺-type starting substrate 41 than is a portion (the first portion 40a) that is closer to the active region 10 than is the recessed portion.

At this time, in the second embodiment, the etching for forming the drop 31 is stopped at the p-type base region 4 and the p-type base region 4 is partially left. Next, by ion implantation, the n⁺-type source regions 5, the p⁺⁺-type contact regions 6, the p⁺⁺-type outer peripheral contact region 21, the p-type regions (the p⁻-type region 32a, the p⁻-type region 32b) of the JTE structure 32, and the n⁺-type channel stopper region 34 are selectively formed. In the second embodiment, in a region between the JTE structure 32 and the n⁺-type channel stopper region 34, an n-type impurity is implanted and the p⁺-type outer peripheral region 13 that was left is converted to an n-type. Thereafter, processes similar to those of to the first embodiment are performed, whereby the silicon carbide semiconductor device according to the second embodiment is completed.

As described above, according to the second embodiment, affects similar to those of the first embodiment are obtained. Further, according to the second embodiment, the n-type current spreading region 3 and the p⁺-type base region 4 are left, the mesa structure is formed, and the p-type region between the JTE structure and the channel stopper region is converted to an n-type. As a result, even in an instance in which the amount of etching when the mesa structure is formed is reduced and the p-type region is left, the thickness of a region where the JTE structure and the p-type regions of the second parallel pn layer may be set to be 0.1 µm or less.

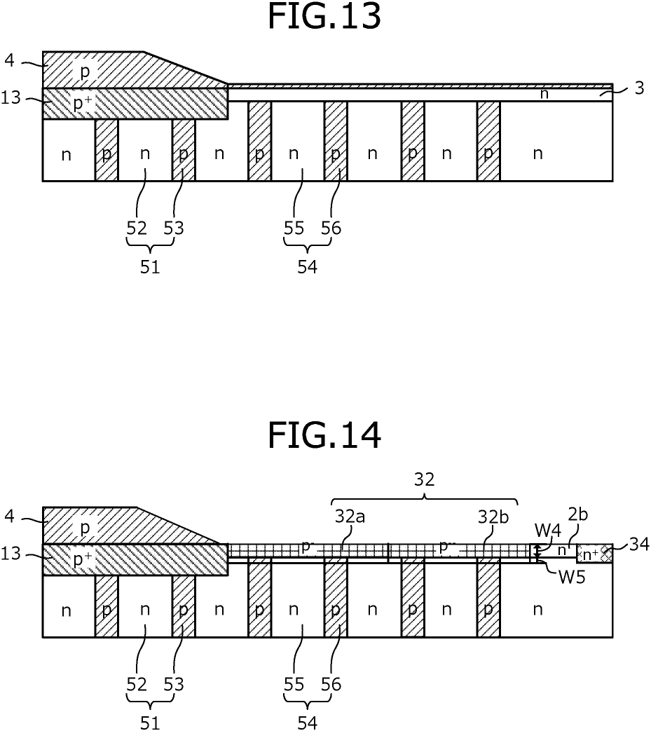

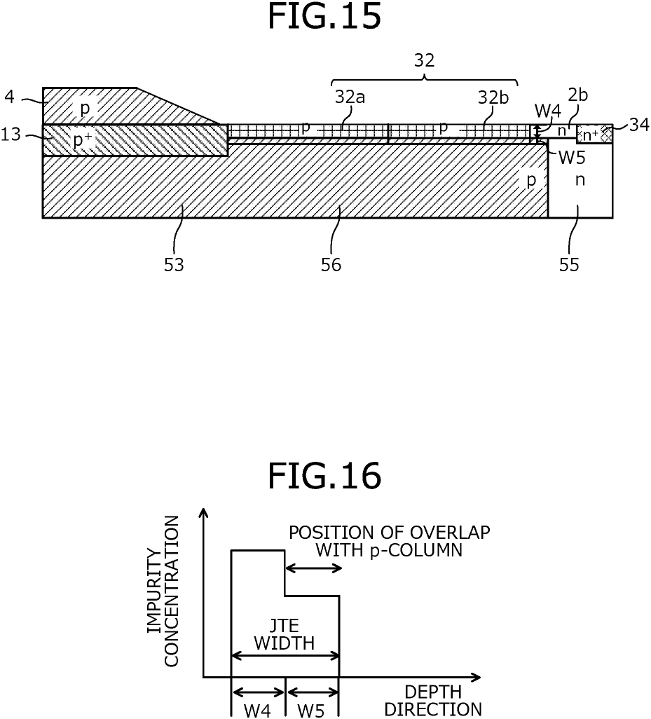

Next, a structure of a silicon carbide semiconductor device according to a third embodiment is described. FIGS. 14 and 15 are detailed cross-sectional views of the JTE structure of the silicon carbide semiconductor device according to the third embodiment. A layout when the silicon carbide semiconductor device according to the third embodiment is viewed from the front side of the semiconductor substrate thereof and a cross-section of the structure of the active region are the same as those of the first embodiment and thus, description thereof is omitted hereinafter (refer to FIGS. 1 and 2). FIGS. 14 and 15 are cross-sectional views of the structure along in cutting line A2-A3 and cutting line A4-A5 in FIG. 1. FIG. 16 is a graph depicting impurity concentration of the JTE structure of the silicon carbide semiconductor device according to the third embodiment.

The silicon carbide semiconductor device according to the third embodiment differs from the first and second embodiments in that the thickness of the region where the JTE structure 32 and the p-type regions 56 of the second parallel pn layer overlap is not prescribed. Instead, in the third embodiment, a p-type impurity concentration at a depth position of the JTE structure 32 is lowered, thereby forming a structure in which increases in the concentration at the position of overlap are suppressed. For example, as depicted in FIG. 16, in the JTE structure 32, the impurity concentration of a portion overlapping the p-type regions 56 and having a width W5 has a lower box profile than the impurity concentration of a portion not overlapping the p-type regions 56 and having a width W4.

As a result, without local increases in the p-type impurity concentration in the JTE structure 32, a depletion region may spread uniformly in the JTE structure 32 without leaving neutral regions in the JTE structure 32 when high voltage is applied to the semiconductor device, the desired breakdown voltage may be sustained, and decreases in the breakdown voltage of the edge termination region may be suppressed.

Next, a method of manufacturing the silicon carbide semiconductor device according to the third embodiment is described. In the third embodiment, similarly to the first embodiment, the semiconductor substrate (the semiconductor wafer) 40 is fabricated in which the epitaxial layers 42, 43 are sequentially stacked on the n⁺-type starting substrate 41 and the first and second parallel pn layers 51, 54 are included in the epitaxial layer 42. Next, the portion of the p-type epitaxial layer 43 at least in the edge termination region 30 is removed by etching, thereby, forming at the front surface of the semiconductor substrate 40, the drop 31 that recesses a portion (the second portion 40b) that is closer to the chip end than is the active region 10, to be closer to the n⁺-type starting substrate 41 than is a portion (the first portion 40a) that is closer to the active region 10 than is the recessed portion.

Next, by ion implantation, the n⁺-type source regions 5, the p⁺⁺-type contact regions 6, the p⁺⁺-type outer peripheral contact region 21, the p-type regions (the p⁻-type region 32a, the p⁻-type region 32b) of the JTE structure 32, and the n⁺-type channel stopper region 34 are each selectively formed. In the third embodiment, for example, first, portions where the JTE structure 32 overlaps the p-type regions 56 are formed by ion implantation; next, portions where the JTE structure 32 do not overlap the p-type regions 56 are formed having a higher impurity concentration by increasing the number of ion implantation sessions. As a result, the JTE structure 32 may be formed so that the impurity concentration of the portions having the width W5 and where the JTE structure 32 overlaps the p-type regions 56 has a box profile impurity concentration that is lower than that of the portions having the width W4 and where the JTE structure 32 does not overlap the p-type regions 56. Thereafter, processes similar to those of the first embodiment are performed, whereby the silicon carbide semiconductor device according to the third embodiment is completed.

Further, the JTE structure 32 of the third embodiment may be formed by depositing a p-type layer on the second parallel pn layer 54 by epitaxial growth, the p-type layer having an impurity concentration is lower than that of the p⁻-type region 32a and the p⁻⁻-type region 32b. Nonetheless, in this method, labor for the epitaxial growth is necessary and a greater amount of labor is necessary as compared to formation by ion implantation.

As described above, according to the third embodiment, effects similar to those of the first embodiment are obtained. Further, according to the third embodiment, the structure is such that the p-type impurity concentration at a depth position of the JTE structure is reduced, whereby increases in the concentration at positions of overlap are suppressed. Thus, the JTE structure may be formed by merely changing an existing process to ion implantation.

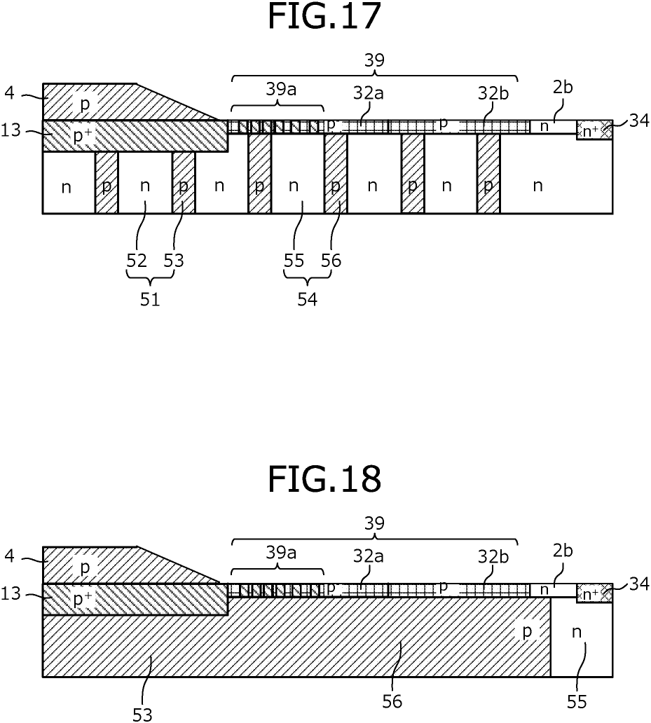

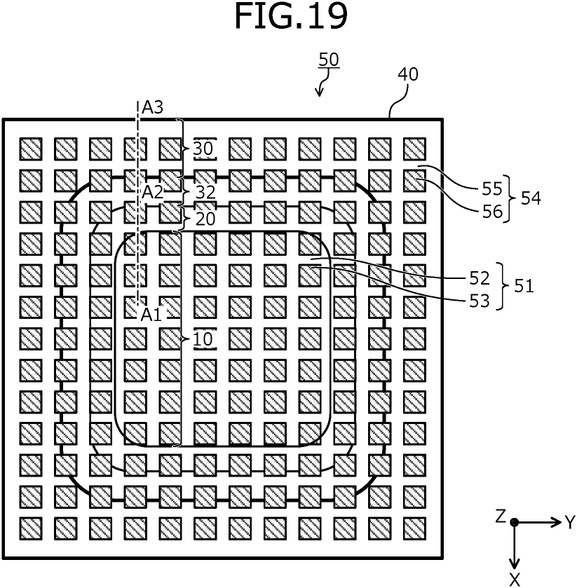

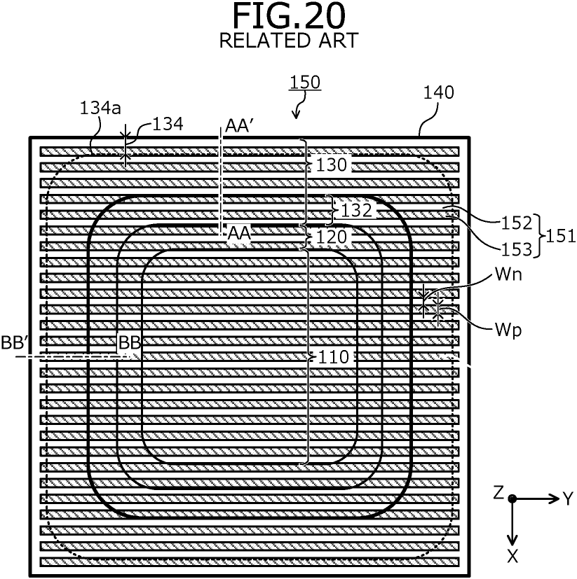

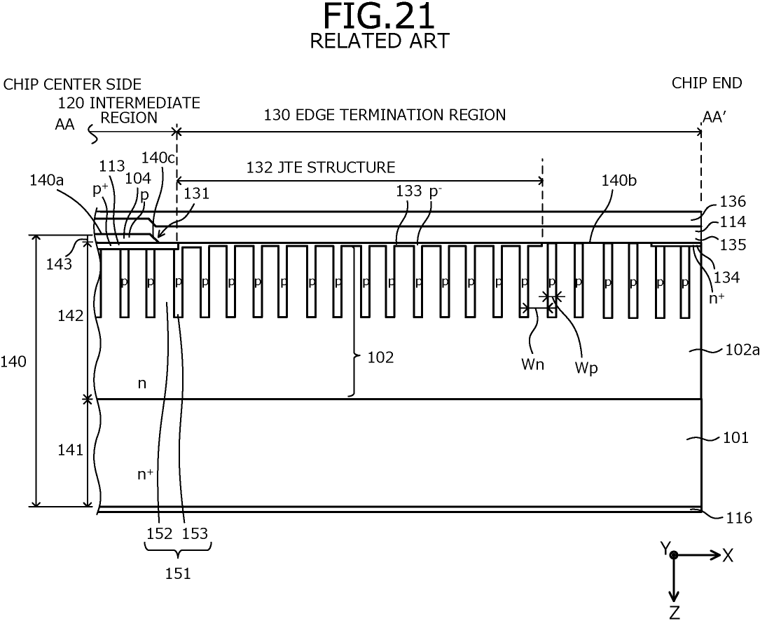

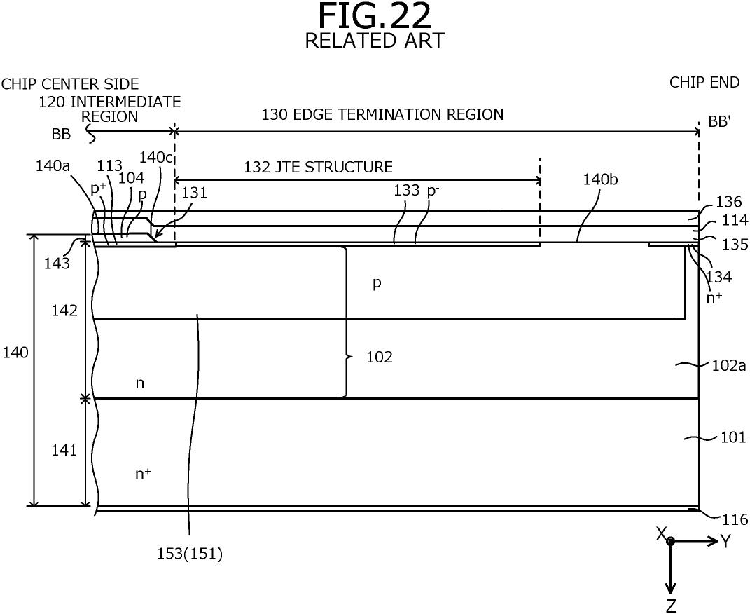

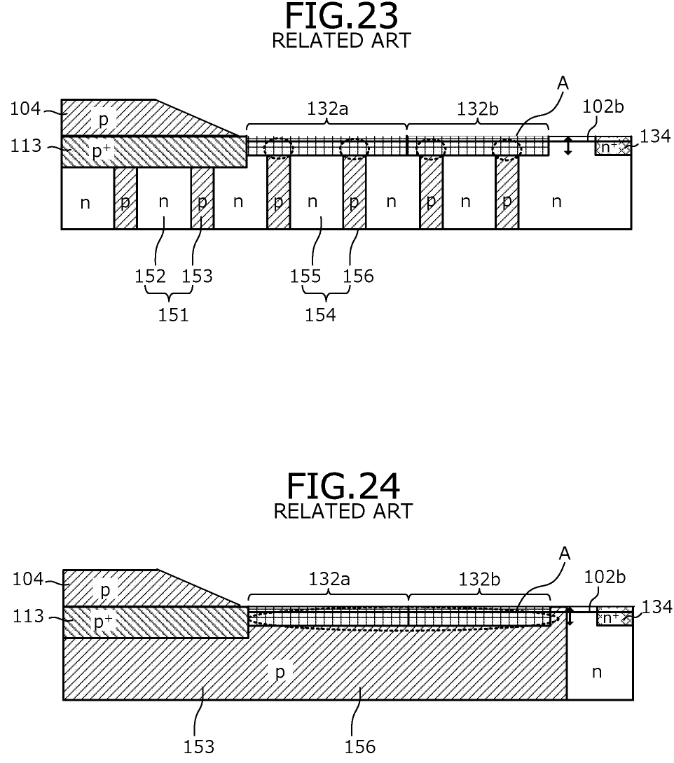

Next, a structure of a silicon carbide semiconductor device according to a fourth embodiment is described. FIGS. 17 and 18 are detailed cross-sectional views of the JTE structure of the silicon carbide semiconductor device according to the fourth embodiment. A layout when the silicon carbide semiconductor device according to the fourth embodiment is viewed from the front side of the semiconductor substrate thereof and a cross-section of the structure in the active region are the same as those of the first embodiment and thus, description thereof is omitted hereinafter (refer to FIGS. 1 and 2). FIGS. 17 and 18 are cross-sectional views of the structure along cutting line A2-A3 and cutting line A4-A5 in FIG. 1, respectively.

In the silicon carbide semiconductor device according to the fourth embodiment, the JTE structure 32 is a spatial modulation JTE structure 39. The spatial modulation JTE structure 39 is a structure in which the p-type regions (the p⁻-type region 32a, the p⁻⁻-type region 32b) that are adjacent to each other and configure the JTE structure 32 are disposed along with a spatial modulation region 39a having an impurity concentration distribution spatially equivalent to an intermediate impurity concentration of these two regions, and an overall impurity concentration distribution of the JTE structure 32 gradually decreases in an outward direction (in a direction to the chip end). FIGS. 17 and 18 depict an example in which the spatial modulation region 39a is disposed in the p⁻-type region 32a. The spatial modulation region 39a may be disposed in the p⁻⁻-type region 32b, or may be disposed in both the p⁻-type region 32a and the p⁻⁻-type region 32b, or may be disposed between the p⁻-type region 32a and the p⁻-type region 32b.

Further, in FIGS. 17 and 18, while the structure is such that the spatial modulation region 39a is disposed in the JTE structure 32 of the first embodiment, the spatial modulation region 39a may be disposed in the JTE structure 32 of any of the first to third embodiments.

The spatial modulation region 39a configuring the spatial modulation JTE structure 39 is formed by two sub-regions that have substantially the same impurity concentration as that of both regions adjacent thereto, the two sub-regions being disposed repeatedly alternating each other in a predetermined pattern. In the example depicted in FIG. 17, in the p⁻-type region 32a, a region of substantially the same impurity concentration as that of the p⁺-type outer peripheral region 13 is disposed in plural with increasingly larger intervals therebetween the closer the region is disposed to the chip end. The overall spatial impurity concentration distribution of the spatial modulation region 39a is determined by the ratio of the width to the impurity concentration of the two sub-regions. Compared to a general JTE structure without the spatial modulation region 39a, the spatial modulation JTE structure 39 is able to ensure a more stable predetermined breakdown voltage.

Further, in the fourth embodiment, the spatial modulation JTE structure 39 and the p-type regions 56 of the second parallel pn layer are adjacent to each other without overlapping. As a result, when high voltage is applied to the semiconductor device, a depletion region may uniformly spread in the spatial modulation JTE structure 39 without leaving neutral regions in the spatial modulation JTE structure 39, the desired breakdown voltage may be sustained, and decreases in the breakdown voltage of the edge termination region 30 may be suppressed.

A method of manufacturing the silicon carbide semiconductor device according to the fourth embodiment suffices to be implemented by forming the spatial modulation JTE structure 39 by forming the spatial modulation region 39a in the JTE structure 32 by ion implantation after forming the JTE structure 32, which is configured by the p⁻-type region 32a and the p⁻⁻-type region 32b, in the method of manufacturing the silicon carbide semiconductor device according to the first embodiment.

As described above, according to the fourth embodiment, effects similar to those of the first embodiment are obtained. Further, according to the fourth embodiment, the spatial modulation region is in the JTE structure. Thus, compared to a general JTE structure without the spatial modulation region, a more stable predetermined breakdown voltage may be ensured.

Next, a structure of a silicon carbide semiconductor device according to a fifth embodiment is described. FIG. 19 is a plan view of a layout when the silicon carbide semiconductor device according to the fifth embodiment is viewed from the front side of the semiconductor substrate thereof. A cross-section of the active region depicted in FIG. 19 is the same as that of the silicon carbide semiconductor device according to the first embodiment and thus, description thereof is omitted hereinafter (refer to FIG. 2). Further, cross-sections of the structure along cutting line A1-A2 and cutting line A2-A3 in FIG. 19 are also the same as those of the silicon carbide semiconductor device according to the first embodiment and thus, description thereof is omitted hereinafter (refer to FIGS. 3 and 4).

Further, details of the JTE structure of the silicon carbide semiconductor device according to the fifth embodiment are similar to those of the structure of the first to fourth embodiments and thus, description thereof is omitted hereinafter (refer to FIGS. 5, 6, 11, 12, 14, 15, 17, and 18). Therefore, similarly to the first embodiment, the thickness of a region where the JTE structure 32 and the p-type regions 56 of the second parallel pn layer overlap is 0.1 µm or less. Alternatively, similarly to the second embodiment, the first surface of the JTE structure 32, opposite to the second surface thereof facing the parallel pn layer 51, may extend beyond (in the direction toward the passivation film 36) the first surface of the p⁺-type region, opposite to the second surface thereof facing the parallel pn layer 51. Further, similarly to the third embodiment, the structure may be such that the JTE structure 32 and the p-type regions 56 of the second parallel pn layer overlap, and the p-type impurity concentration at the depth position of the JTE structure 32 is reduced, whereby increases in the concentration at positions of overlap are suppressed. Further, similarly to the fourth embodiment, the JTE structure 32 may be implemented by the spatial modulation JTE structure 39.

The silicon carbide semiconductor device 50 according to the fifth embodiment differs from the silicon carbide semiconductor device 50 according to the first embodiment in that when viewed from the front side of the semiconductor substrate 40, the p-type regions 53 of the first parallel pn layer 51 and the p-type regions 56 of the second parallel pn layer 54 are disposed in a matrix-like pattern (dotted pattern), while the n-type regions 52 and the n-type regions 55 are disposed in a lattice-like pattern respectively surrounding peripheries of the p-type regions 53 and the p-type regions 56. Further, in the fifth embodiment, the p-type regions 56 of the second parallel pn layer 54 of the edge termination region 30 alone may be disposed in a matrix-like pattern (dotted pattern) while the p-type regions 53 of the first parallel pn layer 51 are in a striped pattern.

In the fifth embodiment, the p-type regions 56 of the second parallel pn layer 54 are disposed in a matrix-like pattern as viewed from the front side of the semiconductor substrate 40, whereby with respect to the direction in which the JTE structure 32 extends (direction of the normal), the second parallel pn layer 54 of the edge termination region 30 has substantially the same cross-sectional structure in the first and second directions X, Y. Thus, design may be simplified as compared to an instance like that of the first to fourth embodiments, in which the cross-section of the structure of the parallel pn layer 51 differs in the first and second directions X, Y with respect to the direction in which the JTE structure 32 extends.

Further, the second parallel pn layer 54 has substantially the same cross-sectional structure in the first and second directions X, Y with respect to the direction in which the JTE structure 32 extends and thus, the breakdown voltage is substantially the same in an entire area of the edge termination region 30. In the edge termination region 30, a portion thereof where the breakdown voltage is relatively low does not occur and thus, the breakdown voltage of the edge termination region 30 may be improved. Further, the breakdown voltage may be set to be substantially the same spanning the entire area of the edge termination region 30 and thus, avalanche current may be borne by the entire area of the edge termination region 30 and the avalanche capability of the edge termination region 30 may be improved.

A method of manufacturing the silicon carbide semiconductor device according to the fifth embodiment suffices to be implemented by forming the p-type regions 53 of the first parallel pn layer 51 and the p-type regions 56 of the second parallel pn layer 54 in a matrix-like pattern (dotted pattern), in the method of manufacturing the silicon carbide semiconductor device according to the first embodiment.

As described above, according to the fifth embodiment, effects similar to those of the first embodiment may be obtained. Further, according to the fifth embodiment, the second parallel pn layer has substantially the same cross-sectional structure in the first and second directions with respect to the direction in which the JTE structure extends and thus, design may be simplified. Further, the second parallel pn layer has substantially the same cross-sectional structure in the first and second directions with respect to the direction in which the JTE structure extends and thus, the breakdown voltage (static breakdown voltage) may be set to be substantially the same spanning the entire area of the edge termination region, and the breakdown voltage of the edge termination region and the avalanche capability (dynamic breakdown voltage) may be further improved.

In the foregoing, the present invention is not limited to the embodiments described above and various modifications within a range not departing from the spirit of the invention are possible. For example, in the embodiments described, between the parallel pn layer and the n⁺-type starting substrate, the impurity concentration of the normal n-type drift region that is not the SJ structure may be higher than the impurity concentration of the n-type regions of the parallel pn layer. Further, the present invention is similarly implemented when the conductivity types (n-type, p-type) are reversed.

According to the invention described above, the thickness of a region where the JTE structure (first semiconductor region of the second conductivity type) and the p-type regions (second second-conductivity-type regions) of the second parallel pn layer overlap is 0.1 µm or less. As a result, when high voltage is applied to the semiconductor device, a depletion region spreads uniformly in the JTE structure without leaving neutral regions in the JTE structure and the desired breakdown voltage may be sustained. Thus, decreases in the breakdown voltage of the edge termination region may be suppressed.

Further, at the front surface of the semiconductor substrate, when the drop is formed that recesses the portion of the front surface closer to the chip end, to be closer to the starting substrate than is a portion that is closer to the active region than is the recessed portion, the n-type current spreading region (third semiconductor region of the first conductivity type) is etched so that the thickness thereof is the same as that of the JTE structure, whereby the p-type regions and the JTE structure may be formed to be in contact with each other without overlapping.

The silicon carbide semiconductor device and the method of manufacturing a silicon carbide semiconductor device according to the invention achieves an effect in that locations where the JTE structure is not depleted may be reduced, whereby the overall breakdown voltage of the silicon carbide semiconductor device may be improved.

As described, the silicon carbide semiconductor device and the method of manufacturing a silicon carbide semiconductor device according to the invention are useful for power semiconductors that have a SJ structure and are used in power converting equipment, power source devices such as those of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate containing silicon carbide, the semiconductor substrate having a first main surface and a second main surface that are opposite to each other, the semiconductor substrate further having an active region and a termination region surrounding a periphery of the active region;
a first parallel pn layer in which a plurality of first first-conductivity-type regions and a plurality of first second-conductivity-type regions are disposed so as to repeatedly alternate with one another in a direction parallel to the first main surface of the semiconductor substrate, the first parallel pn layer being provided in the semiconductor substrate, in the active region;
a second parallel pn layer in which a plurality of second first-conductivity-type regions and a plurality of second second-conductivity-type regions are disposed so as to repeatedly alternate with one another in the direction, the second parallel pn layer being provided in the semiconductor substrate, in the termination region;
a device structure provided between the first main surface of the semiconductor substrate and the first parallel pn layer, in the active region;
a first electrode provided on the first main surface of the semiconductor substrate, the first electrode being electrically connected to the device structure;
a second electrode provided on the second main surface of the semiconductor substrate; and
a first semiconductor region of the second conductivity type configuring a voltage withstanding structure and being electrically connected to the first electrode, the first semiconductor region being selectively provided between the first main surface of the semiconductor substrate and the second parallel pn layer in the termination region, the first semiconductor region surrounding the periphery of the active region, wherein
the first semiconductor region has an overlap area where the first semiconductor region and one of the plurality of second second-conductivity-type regions overlap each other in a plan view of the silicon carbide semiconductor device,
in the overlap area,
the first semiconductor region and the one of the plurality of second second-conductivity-type regions are in contact with each other in a thickness direction, or
between the first semiconductor region and the one of the plurality of second second-conductivity-type regions in the thickness direction, an other second-conductivity-type region is provided and has a thickness of at most 0.1 µm.

2. The silicon carbide semiconductor device according to claim 1, wherein
the overlap area is provided in plurality, and respective ones of the plurality of second second-conductivity-type regions are in contact with the first semiconductor region without the other second-conductivity-type region intervening therebetween.

3. The silicon carbide semiconductor device according to claim 1, further comprising
a second semiconductor region of the second conductivity type, provided on the first parallel pn layer in the active region, the second semiconductor region having a first surface and a second surface opposite to each other, the second surface facing the first parallel pn layer, wherein
the first semiconductor region has a first surface and a second surface opposite to each other, the second surface facing the second parallel pn layer, the first surface of the first semiconductor region being closer to the first electrode than is the first surface of the second semiconductor region.

4. The silicon carbide semiconductor device according to claim 1, wherein
a first impurity concentration of the other second-conductivity-type region is lower than a second impurity concentration of the first semiconductor region in a region overlapping the plurality of second first-conductivity-type regions in the plan view.

5. The silicon carbide semiconductor device according to claim 1, further comprising
in the first semiconductor region, a spatial modulation region in which an impurity concentration distribution of the first semiconductor region decreases in a direction from the active region to the termination region.

6. The silicon carbide semiconductor device according to claim 1, wherein
the plurality of second second-conductivity-type regions is disposed in a matrix-like pattern as viewed from the first main surface of the semiconductor substrate, and
the plurality of second first-conductivity-type regions is disposed in a lattice-like pattern surrounding a periphery of each of the plurality of second second-conductivity-type regions as viewed from the first main surface of the semiconductor substrate.

7. A method of manufacturing a silicon carbide semiconductor device, the method comprising:
preparing a semiconductor substrate that contains silicon carbide, the semiconductor substrate having a first main surface and a second main surface opposite to each other, the semiconductor substrate further having an active region and a termination region surrounding a periphery of the active region;
forming, in the semiconductor substrate in the active region, a first parallel pn layer in which a plurality of first first-conductivity-type regions and a plurality of first second-conductivity-type regions are disposed so as to repeatedly alternate with one another in a direction parallel to the first main surface of the semiconductor substrate;
forming, in the semiconductor substrate in the termination region, a second parallel pn layer in which a plurality of second first-conductivity-type regions and a plurality of second second-conductivity-type regions are disposed so as to repeatedly alternate with one another in the direction;
forming a device structure in the active region, between the first main surface of the semiconductor substrate and the first parallel pn layer;
forming a first electrode on the first main surface of the semiconductor substrate, the first electrode being electrically connected to the device structure;
forming a second electrode on the second main surface of the semiconductor substrate;
forming a third semiconductor region of the first conductivity type as a pre-first semiconductor region, at surfaces of the first parallel pn layer and the second parallel pn layer;
etching the pre-first semiconductor region on the second parallel pn layer in the termination region and partially removing a surface layer thereof in the termination region; and
ion-implanting an impurity of the second conductivity type in a remaining pre-first semiconductor region in the termination region thereby to selectively form, between the first main surface of the semiconductor substrate and the second parallel pn layer, a first semiconductor region of a second conductivity type surrounding the periphery of the active region, the first semiconductor region configuring a voltage withstanding structure and being electrically connected to the first electrode, wherein
the pre-first semiconductor region on the second parallel pn layer is etched so that a thickness thereof is the same as a thickness of the first semiconductor region, whereby a region where one of the plurality of second second-conductivity-type regions and the first semiconductor region overlap has a thickness of at most 0.1 µm.

8. The method according to claim 7, further comprising
forming a second semiconductor region of the second-conductivity-type at a surface of the third semiconductor region as a part of the pre-first semiconductor region, after forming the third semiconductor region but before etching the pre-first semiconductor region, wherein
the etching the pre-first-semiconductor region includes etching the second semiconductor region so as to partially leave the second semiconductor region on the third semiconductor region in the termination region,
the impurity of the second conductivity type is ion-implanted in a remaining pre-first semiconductor region that includes a remaining second semiconductor region and the third semiconductor region, thereby to form the first semiconductor region, and
the method further comprises, before ion-implanting the impurity of the second conductivity type, ion-implanting an impurity of the first conductivity type in a converting area that is outside an area where the first semiconductor region is to be formed, the converting area being closer to an end of the semiconductor substrate than is the first semiconductor region, thereby, converting the converting area of the second semiconductor region to the first conductivity type.
